(19) United States
(12) Patent Application Publication
(10) Pub. No.: US 2007/0152249 A1
(43) Pub. Date: Jul. 5, 2007

(54) METHOD FOR FABRICATING CMOS IMAGE SENSOR

(76) Inventor: Bi O Lim, Seoul (KR)

Correspondence Address: SHERR & NOURSE, PLLC, 620 HERNDON PARKWAY, SUITE 200, HERNDON, VA, 20170, US

(21) Appl. No.: 11/615,823

(22) Filed: Dec. 22, 2006

(30) Foreign Application Priority Data
Dec. 29, 2005 (KR) 10-2005-0133827

(51) Int. Cl. H01L 31/113; H01L 21/00

(52) U.S. Cl. 257/292; 257/294; 438/70; 257/E27.133

(57) ABSTRACT

There is provided a method of manufacturing a CMOS image sensor, in which an anti-reflection coating layer is additionally formed on a pad electrode so that it is possible to prevent the pad electrode from being corroded by development solution of a sequential photolithography process and to bond an external driving circuit and the pad electrode to each other without defect.

The present application claims priority under 35 U.S.C. 119 and 35 U.S.C. 365 to Korean Patent Application No. 10-2005-0133827 (filed on Dec. 29, 2005), which is hereby incorporated by reference in its entirety.

### BACKGROUND

In general, image sensors are semiconductor devices for converting an optical image into an electrical signal.

Among the image sensors, the CMOS image sensor is a device employing a switching mode to sequentially detect an output by providing photodiodes corresponding to the number of pixels through a CMOS technology that uses peripheral devices, such as a control circuit and a signal processing circuit.

Studies and research on image sensor fabrication techniques have improved photosensitivity.

The CMOS image sensor is composed of a pixel array unit including photodiodes for sensing light and a CMOS logic circuit for processing the detected light into electrical signals, to convert them into data. In order to improve photosensitivity, either the area occupied by the photodiodes must be increased, or a photo-gathering technology must be used to collect more light in the photodiode area by focussing the light path and forming a micro-lens over the upper portion of the photodiodes.

CMOS image sensors are divided into 3T-type CMOS image sensors, 4T-type CMOS image sensors, and 5T-type CMOS image sensors in accordance with the number of transistors. The 3T-type CMOS image sensor is composed of one photodiode and 3 transistors. The 4T-type CMOS image sensor is composed of 4 transistors. An equivalent circuit and a layout for a unit pixel of the 3T-type CMOS image sensor will be described as follows.

FIG. 1 is an equivalent circuit diagram of a 3T CMOS image sensor, and FIG. 2 is a layout diagram illustrating a unit pixel of the 3T MOS image sensor.

The unit pixel of the 3T-type CMOS image sensor, as illustrated in FIG. 1, is composed of one photodiode and three nMOS transistors T1, T2, and T3. The cathode of the photodiode PD is connected to the drain of the first nMOS transistor T and the gate of the second nMOS transistor T2.

In addition, sources of the first and second nMOS transistors T1 and T2 are connected to a power line feeding a reference voltage VR, and a gate of the first nMOS transistor T1 is connected to a reset line feeding a reset signal RST.

Also, the source of the third nMOS transistor T3 is connected to the drain of the second nMOS transistor. The drain of the third nMOS transistor T3 is connected to a reading circuit (not shown) through a signal line). The gate of the third nMOS transistor T3 is connected to a column selection line to which the selection signal SLCT is supplied.

Therefore, the first nMOS transistor T1 is referred to as a reset transistor Rx, the second nMOS transistor T2 is referred to as a drive transistor Dx, and the third nMOS transistor T3 is referred to as a selection transistor Sx.

In the unit pixel of the 3T CMOS image sensor, as illustrated in FIG. 2, an active region 10 is defined so that one photodiode 20 is formed in a wide part of the active region 10 and that the gate electrodes 120, 130, and 140 of the overlapping three transistors are formed in the remaining part of the active region 10.

That is, the reset transistor Rx is formed by the gate electrode 120, the drive transistor Dx is formed by the gate electrode 130, and the selection transistor Sx is formed by the gate electrode 140.

Here, dopants are implanted into the part excluding the lower parts of the gate electrodes 120, 130, and 140 in the active region 10 of the transistor, so that the source and drain regions of the transistors are formed.

Accordingly, supply voltage Vdd is applied to the source/drain area between the reset transistor Rx and the drive transistor Dx, and a source/drain area formed at one side of the select transistor Sx is connected to a reading circuit (not shown).

Although not shown in the drawing, the gate electrodes 120, 130, and 140 are connected to the signal lines and each signal line includes a pad at one end to be connected to an external driving circuit.

Hereinafter, a method of manufacturing a CMOS image sensor will be described with reference to the attached drawings.

FIGS. 3A to 3C are sectional views showing a method of manufacturing the CMOS image sensor.

As illustrated in FIG. 3A, an oxide layer is deposited over a semiconductor substrate (not shown) divided into a pixel array unit (P) and a logic circuit unit (L) to form an interlayer insulating layer 61. A chemical mechanical polishing (CMP) process is performed to planarize the surface of the interlayer insulating layer 61.

Various interconnections, transistors, and photodiodes are provided on the semiconductor substrate.

Then, a metal such as aluminum may be sputtered over the interlayer insulating layer 61. The deposited metal may be patterned by a photolithography process to form a pad electrode 53 in the logic circuit unit L.

Then, an oxide layer is deposited over the entire surface including the pad electrode 53. The surface of the oxide layer may be polished by the CMP process to form a protective layer 65.

The protective layer 65 over the pad electrode 53 is selectively etched by the photolithography process to form a via hole for bonding the pad electrode to an external driving circuit.

Then, as illustrated in FIG. 3B, photoresist is coated over the entire surface including the protective layer 65. A photolithography process is performed using a mask to selectively remove a part of the photoresist and to form a color filter layer 40 having a pattern in the pixel array unit P.

Then, the photoresist is coated over the entire surface including the color filter layer 40, the surface of the photoresist is polished by the CMP process. Another photolithography process is performed using a mask to selectively remove the photoresist of the logic circuit unit and to thus form a planarization layer 10 that buries the color filter layer.

Then, as illustrated in FIG. 3C, the planarization layer 10 is coated with more photoresist, the surface of the photoresist is polished by the CMP process, and another photolithography process is performed using a mask to pattern the photoresist in the form of a trapezoid. Then, a reflowing process is carried out to allow the edges of the photoresist pattern to be rounded, thereby obtaining a micro lens 50.

However, the method of manufacturing the CMOS image sensor described above has the following problems.

The pad electrode is opened to the outside in order to bond the pad electrode to the external driving circuit. However, since the color filter layer formation process, the planarization layer formation process, and the micro lens formation process are performed after the pad electrode opening process, the pad electrode is corroded by the development solution used in the photolithography process.

FIGS. 4A and 4B illustrate the pad electrode corrosion caused by the photolithography process. When the pad electrode 53 is severely corroded as shown in A, it is difficult to bond the pad electrode and the external driving circuit to each other.

Rework can be performed during the color filter layer formation process and the micro lens formation process. The number of times the rework process may be used is limited because the pad electrode can be corroded by the development solution.

### SUMMARY

Embodiments relate to a method of manufacturing a CMOS image sensor. More specifically, embodiments relate relates to a method of manufacturing a CMOS image sensor, in which it is possible to prevent a pad electrode from being corroded by a development solution of a photolithography process so that an external driving circuit and the pad electrode are bonded to each other without defects.

Embodiments relate to a method of manufacturing a CMOS image sensor, in which an anti-reflection coating layer is formed over the pad electrode so that it is possible to prevent the pad electrode from being corroded by the development solution of sequential photolithography processes and to bond an external driving circuit and a pad electrode to each other without defects. Embodiments relate to a method of manufacturing a CMOS image sensor the method comprising providing a semiconductor substrate divided into a pixel array area and a logic circuit area; forming interconnections over the semiconductor substrate; forming an interlayer insulating layer over an entire surface of the semiconductor substrate including the interconnections; depositing a metal layer and an anti-reflection coating layer over the interlayer insulating layer and patterning the deposited metal layer and anti-reflection coating layer to form a pad electrode; forming a protective layer over the entire surface including the pad electrode; selectively removing the protective layer over the pad electrode to form a via hole; forming a color filter layer over the protective layer; forming a planarization layer for covering the color filter layer; forming micro lenses corresponding to the color filter layer over the planarization layer; and removing the anti-reflection coating layer over the pad electrode exposed through the via hole.

The color filter layer, the planarization layer, and the micro lenses prevent the pad electrode from being corroded by the anti-reflection coating layer when the patterning is performed through the photolithography process.

An external driving circuit is bonded to the pad electrode through a via hole from which the anti-reflection coating layer is removed.

### BRIEF DESCRIPTION OF DRAWINGS

FIG. 1 is an equivalent circuit diagram of a 3T-type CMOS image sensor;

FIG. 2 is a layout diagram illustrating a unit pixel of the 3T-type CMOS image sensor;

FIGS. 3A to 3C are sectional views illustrating a method of manufacturing a CMOS image sensor;

FIGS. 4A and 4B are photographs illustrating corrosion of semiconductor elements; and

FIGS. 5A to 5C are sectional views illustrating processes of a method of manufacturing a CMOS image sensor according to embodiments.

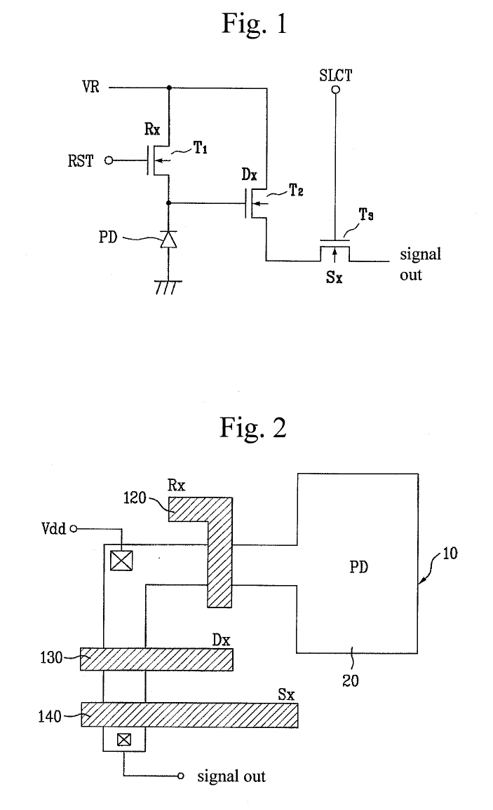

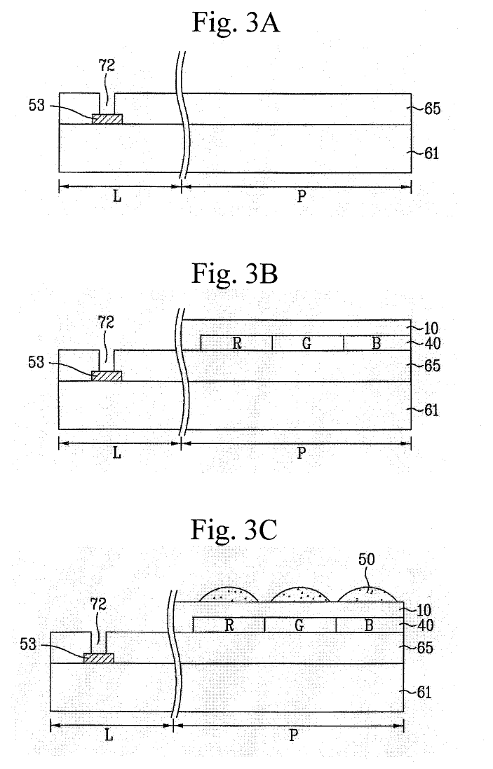

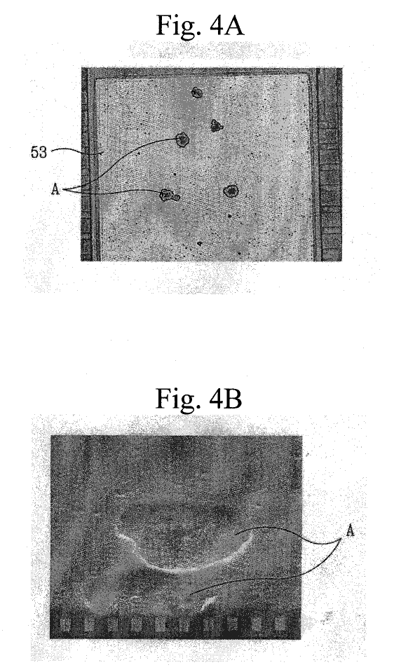

### DETAILED DESCRIPTION

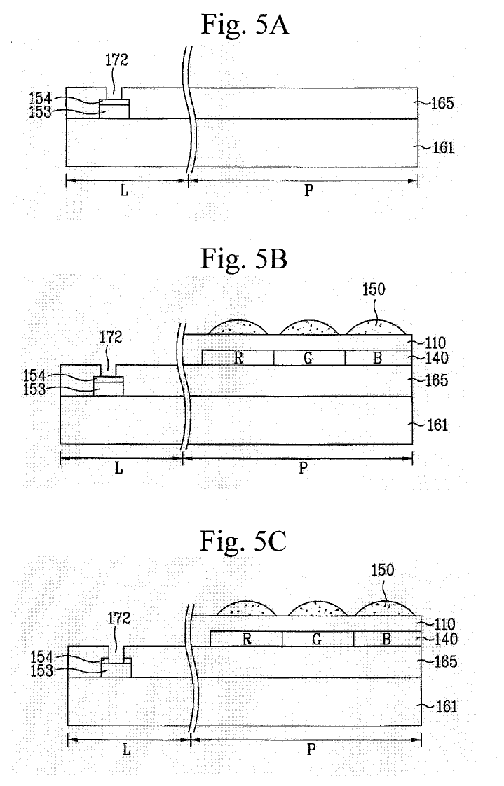

FIGS. 5A to 5C are sectional views illustrating processes of a method of manufacturing a CMOS image sensor according to embodiments.

As illustrated in FIG. 5A, an oxide layer is deposited over a semiconductor substrate (not shown) to form an interlayer insulating layer 161. The substrate may be divided into a pixel array area (P) and a logic circuit area (L). The surface of the interlayer insulating layer 161 is planarized by a CMP process.

Various devices are formed on the semiconductor substrate, which may include any of the following: interconnections having a multi-layer structure and electrically connected to each other through a contact plug, transistors for controlling on/off of signals, R, G, and B-photodiodes for sensing red, green, and blue signals.

A metal such as aluminum may be sputtered over the interlayer insulating layer 161. A silicon nitride (SiN or SiON) may be deposited over the metal material by a physical vapor deposition (PVD) method, a chemical vapor deposition (CVD) method, or an atomic layer deposition (ALD) method. The silicon nitride is patterned by a photolithography process to form a pad electrode 153 and an anti-reflection coating layer 154 in the logic circuit unit (L).

The pad electrode 153 is formed only in the logic circuit unit (L). Since the pad electrode 153 is a power interconnection that receives signals from an external driving circuit, the thickness thereof is large. As an example, while the metal interconnection provided between interlayer insulating layers might be 1,500 to 4,000 Å thick, the pad electrode formed in the logic circuit unit might be 3,000 to 5,000 Å thick.

Since the anti-reflection coating layer must protect the pad electrode during sequential photolithography processes, the anti-reflection coating layer may be 50 to 1,000 Å thick. When the anti-reflection coating layer is too thin, the anti-reflection coating layer cannot perform its function as an etch stop layer. When the anti-reflection coating layer is too thick, it is difficult to remove it when other processing steps are complete. Therefore, the anti-reflection coating layer must have a proper thickness for the type of processes used elsewhere on the chip.

A barrier layer may be formed under the pad electrode. A laminated layer of TiN/Ti, Ta, TaN, WN, TaC, WC, TiSiN, and TaSiN can be used as the barrier layer.

An oxide layer is deposited over the entire surface including the pad electrode 153. The surface of the oxide layer is polished by the CMP process to form a protective layer 165. The protective layer 165 may be made thick in order to remove a step difference between the pixel array unit and the logic circuit unit that is caused by the pad electrode. In order to prevent the pad electrode 153 from being polished, the CMP process is stopped 3,000 Å to 5,000 Å away from the pad electrode. Therefore, the protective layer 165 formed over the interlayer insulating layer 161 has a thickness of 8,000 Å to 14,000 Å.

The protective layer 165 over the pad electrode 153 is selectively etched by a photolithography process to form a via hole 172 for bonding the pad electrode to an external driving circuit. Since the anti-reflection coating layer 154 functions as an etch stop layer, the development solution does not penetrate the pad electrode.

Then, as illustrated in FIG. 5B, the entire surface including the protective layer 165 is coated with the photoresist. A photolithography process is performed using a mask to selectively remove a part of the photoresist and to form a color filter layer 140 having a pattern in the pixel array unit (P). The color filter layer may contain pigments representing primary colors in the photoresist. In general, the pigments of R, G, and B (red, green, and blue) are used. Therefore, the color filter layers include a R-color layer, a G-color layer, and a B-color layer.

The entire surface including the color filter layer 140 is coated with the photoresist, the surface of the photoresist is polished by the CMP process, and the photolithography process is performed using a mask to selectively remove the photoresist of the logic circuit unit and to thus form a planarization layer 110 that buries the color filter layer. The development layer does not penetrate the pad electrode due to the anti-reflection coating layer 154.

A plurality of micro lenses 150 corresponding to the color filter layer 140 are formed over the planarization layer 110.

Convex micro lenses may be formed to focus light on the photodiodes. The micro lenses may be patterned by performing the photolithography process.

Specifically, the micro lenses will be formed over the planarization layer 154 from a coating of photoresist. The photoresist is exposed using a defocus phenomenon to pattern the photoresist into the shape of a trapezoid.

Then, the trapezoidal photoresist pattern is heated to the melting point to reflow. The photoresist pattern becomes rounded with flexibility to complete the micro lenses 150.

The pad electrode is also protected by the anti-reflection coating layer during the formation of the micro lenses.

Finally, as illustrated in FIG. 5C, the anti-reflection coating layer 154 exposed through the via hole 172 may be etched by a reactive ion etch (RIE) method or a chemical dry etching method to expose the pad electrode 153 to the outside.

Then, although not shown, the external driving circuit is connected to the pad electrode through the via hole. At this time, since the pad electrode is not corroded, the pad electrode and the external driving circuit are bonded without defects.

The above-described method of manufacturing the CMOS image sensor according to the embodiments has the following effects.

The anti-reflection coating layer is formed over the pad electrode to prevent the pad electrode from being corroded by the development solution in the sequential photolithographic processes of forming the color filter layer, the planarization layer, and the micro lenses.

Therefore, it is possible to effectively remove the problem of the pad electrode being attacked during the formation of the CMOS image sensor. Therefore, it is possible to bond the external driving circuit and the pad electrode to each other without defects.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method of manufacturing a CMOS image sensor, the method comprising:
providing a semiconductor substrate divided into a pixel array area and a logic circuit area;
forming interconnections over the semiconductor substrate;
forming an interlayer insulating layer over an entire surface of the semiconductor substrate including the interconnections;
depositing a metal layer and an anti-reflection coating layer over the interlayer insulating layer and patterning the deposited metal layer and anti-reflection coating layer to form a pad electrode;
forming a protective layer over the entire surface including the pad electrode;
selectively removing the protective layer over the pad electrode to form a via hole;
forming a color filter layer over the protective layer;
forming a planarization layer for covering the color filter layer;
forming micro lenses corresponding to the color filter layer over the planarization layer; and
removing the anti-reflection coating layer over the pad electrode exposed through the via hole.

2. The method of claim 1, wherein the color filter layer, the planarization layer, and the micro lenses are formed only in the pixel array area.

3. The method of claim 1, wherein the color filter layer, the planarization layer, and the micro lenses are patterned through a photolithographic process.

4. The method of claim 1, wherein the pad electrode is formed in a logic circuit area.

5. The method of claim 1, wherein the metal layer comprises aluminum.

6. The method of claim 1, wherein the anti-reflection coating layer comprises one of the group including SiN or SiON.

7. The method of claim 1, wherein the anti-reflection coating layer has a thickness between 50 Å and 1,000 Å.

8. The method of claim 1, the step of removing the anti-reflection coating layer over the pad electrode exposed through the via hole is performed by a reactive ion etch (RIE) method.

9. The method of claim 1, the step of removing the anti-reflection coating layer over the pad electrode exposed through the via hole is performed by a chemical dry etching method.

10. The method of claim 1, wherein an external driving circuit is bonded to the pad electrode through a via hole from which the anti-reflection coating layer is removed.
